(19) United States
(12) Patent Application Publication
(10) Pub. No.: US 2021/0111205 A1
(43) Pub. Date: Apr. 15, 2021

(54) OPTOELECTRONIC DEVICE HAVING A DIODE PUT UNDER TENSILE STRESS BY AN INVERSE PIEZOELECTRIC EFFECT

(71) Applicant: COMMISSARIAT A L'ENERGIE ATOMIQUE ET AUX ENERGIES ALTERNATIVES, Paris (FR)

(72) Inventors: Abdelkader ALIANE, Grenoble cedex 09 (FR); Luc ANDRE, Grenoble cedex 09 (FR); Jean-Louis OUVRIER-BUFFET, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 17/044,510

(22) PCT Filed: Apr. 15, 2019
(86) PCT No.: PCT/FR2019/050882

§ 371 Date: Oct. 1, 2020

(30) Foreign Application Priority Data
Apr. 18, 2018 (FR) 1853386

(51) Int. Cl. H01L 27/146; H01L 31/103; H01L 31/105; H01L 41/09; H01L 41/187; H01L 41/39; H01L 31/02

(52) U.S. Cl. CPC H01L 27/14603; H01L 27/14649; H01L 31/1037; H01L 31/02005; H01L 41/09; H01L 41/1876; H01L 41/39; H01L 31/105

(57) ABSTRACT

The invention relates to an optoelectronic device (1) comprising:
at least one diode (2) that has a semiconductor portion (20) in which a PN or PIN junction is formed;
a peripheral conductive layer (40) that extends in the main plane in such a way as to surround the semiconductor portion (20);
a peripheral piezoelectric portion (30) that extends in the main plane in such a way as to surround the semiconductor portion (20);
a first polarizing electric circuit (30) capable of generating an electric field in the peripheral piezoelectric portion (30) by applying an electric potential at least to the peripheral conductive layer (40) so as to induce a deformation of the peripheral piezoelectric portion (30) in the direction of the main plane, thus causing a tensile deformation of the semiconductor portion (20) in the main plane.

### TECHNICAL FIELD

The field of the invention is that of optoelectronic devices comprising at least one diode made based on a tensilely strained semiconductor compound. The invention is notably applicable to the field of detection of light radiation belonging, for example, to the near infrared, the one or more diodes of the optoelectronic device then being made based on tensilely strained germanium.

### PRIOR ART

In various microelectronic or optoelectronic applications, it may be advantageous to use a layer made of a crystalline, and preferably single-crystal, semiconductor compound having a tensile mechanical strain. This is notably the case with certain light sources the material of the emissive layer of which has, unstrained, an indirect band structure, the band structure then being made direct by applying a sufficient tensile strain. The crystalline semiconductor compound may be a compound based on germanium, for example germanium, germanium-tin, or even silicon-germanium.

Thus, document US2014/0291682 describes an avalanche photodiode the absorbing semiconductor layer of which is made of tensilely strained germanium. The photodiode is then suitable for absorbing light radiation up to a cut-off wavelength longer than 1550 nm, which is the cut-off wavelength of absorption of relaxed germanium. To this end, the germanium layer is coated with a strain-inducing layer formed from a stack of sublayers made of silicon nitride, silicon oxide and amorphous silicon. However, this photodiode notably has the drawback of being obtained using techniques for engineering mechanical strain by depositing a stack of thin layers, this possibly making the fabricating process complex.

Document EP3151265 describes a diode-comprising optoelectronic device containing a tensilely strained semiconductor layer made based on germanium. The semiconductor layer is strained via prior localized structuring of the layer, then via suspension of the structured layer above a substrate, followed by attachment to the latter by direct bonding. A consolidating anneal is lastly carried out in order to improve the mechanical strength of the strained structured layer bonded to the substrate. However, this optoelectronic device notably has the drawback of being obtained using a relatively complex fabricating process. In addition, as in the preceding document, control of the value of the tensile strain actually experienced by the semiconductor layer may be particularly difficult.

There is therefore a need to provide an optoelectronic device the value of the tensile mechanical strain experienced by the one or more diodes of which is controllable more simply and more precisely. There is also a need to provide such an optoelectronic device that is capable of having a low bulk and of providing a high spatial resolution when it comprises a matrix-array of diodes, and that is furthermore capable of being obtained using a simplified fabricating process.

### DISCLOSURE OF THE INVENTION

One objective of the invention is to at least partially remedy the drawbacks of the prior art, and more particularly to provide an optoelectronic device comprising one or more diodes able to be tensilely strained actively. Another objective thereof is to provide an optoelectronic device having a low bulk, and capable of being obtained with a simplified fabricating process. Yet another objective thereof is to provide an optoelectronic device comprising a matrix-array of diodes having a high spatial resolution.

To this end, the subject of the invention is an optoelectronic device comprising:
at least one diode, comprising a semiconductor portion having:
   a first face and an opposite second face that are substantially parallel to a main plane and that are connected to each other by a lateral border, and
   a PN or PIN junction formed by:
      a first region that is doped according to a first conductivity type, and
      a second region that is doped according to a second conductivity type opposite the first type and that extends from the lateral border;
a peripheral conductive layer that is made of at least one electrically conductive material and that extends, in the main plane, in contact with the second doped region so as to encircle the semiconductor portion;
a peripheral piezoelectric portion that is made of at least one piezoelectric material and that extends, in the main plane, in contact with the peripheral conductive layer so as to encircle the semiconductor portion;
   a first electrical circuit for biasing the peripheral piezoelectric portion, said circuit being suitable for generating an electric field in the peripheral piezoelectric portion by applying an electrical potential at least to the peripheral conductive layer, so as to induce a deformation of the peripheral piezoelectric portion that is oriented in the main plane, thus causing the semiconductor portion to be tensilely strained in the main plane.

The following are certain preferred but non-limiting aspects of this optoelectronic device.

Preferably, the peripheral conductive layer and the peripheral piezoelectric portion encircle the semiconductor portion continuously.

Preferably, the peripheral conductive layer entirely covers the lateral border of the semiconductor portion along an axis orthogonal to the main plane, and the peripheral piezoelectric portion entirely covers the peripheral conductive layer along said orthogonal axis.

Preferably, the lateral border extends substantially orthogonally to the main plane.

The peripheral piezoelectric portion may have a thickness at least equal to that of the semiconductor portion.

The optoelectronic device may comprise a second electrical circuit for biasing the diode, said circuit being suitable for applying said electrical potential to the second doped region by way of the peripheral conductive layer and a different electrical potential to the first doped region.

The first doped portion may extend from the first face and be away from the lateral border.

The diode may comprise:
a PIN junction, the first doped region being encircled in the main plane and making contact with an unintentionally doped region, or
a PN junction, the first doped region being encircled in the main plane and making contact with the second doped region.

Preferably, the semiconductor portion is made based on germanium.

Preferably, the peripheral piezoelectric portion is made of PZT.

Preferably, the peripheral piezoelectric portion is, in the main plane, substantially coplanar with the diode.

The optoelectronic device may comprise a matrix-array of coplanar diodes the semiconductor portions of which are electrically isolated from each other by a peripheral piezoelectric portion that, in the main plane, extends continuously.

The optoelectronic device may comprise a metallization encircling each semiconductor portion and resting on an end of the peripheral piezoelectric portion that emerges onto the first face or the second face, the first circuit being suitable for applying an electrical potential difference between the metallization and the peripheral conductive layer of each diode, so as to cause a compressive deformation of the peripheral piezoelectric portion in the main plane.

The optoelectronic device may comprise a second peripheral conductive layer that is arranged so that the peripheral piezoelectric portion is interposed, in the main plane, between the second peripheral conductive layer and said peripheral conductive layer that makes contact with the semiconductor portion, the first circuit being suitable for applying an electrical potential difference between said peripheral conductive layers, so as to cause a deformation of the peripheral piezoelectric portion in the main plane in a direction opposite to the semiconductor portion.

The invention also relates to a process for fabricating an optoelectronic device according to any one of the preceding features, comprising at least the following steps:
producing at least the semiconductor portion;
conformally depositing the peripheral conductive layer on and in contact with the lateral border of the semiconductor portion;
forming the peripheral piezoelectric portion by depositing a piezoelectric material on and in contact with a face of the peripheral conductive layer that is opposite to the lateral border.

### BRIEF DESCRIPTION OF THE DRAWINGS

Other aspects, aims, advantages and features of the invention will become more clearly apparent upon reading the following detailed description of preferred embodiments thereof, which description is given by way of non-limiting example and with reference to the appended drawings, in which:

FIG. 1A is a partial and schematic cross-sectional view of an optoelectronic device according to a first embodiment in which the optoelectronic device comprises at least one diode;

FIG. 1B is a partial and schematic cross-sectional view of an optoelectronic device according to a second embodiment in which the optoelectronic device comprises a matrix-array of diodes;

FIGS. 2A and 2B are partial and schematic views from above of variants of the optoelectronic device illustrated in FIG. 1A, one of which (FIG. 2A) is of circular shape and the other (FIG. 2B) is of square shape, and FIG. 2C is a partial and schematic view from above of an optoelectronic device similar to that illustrated in FIG. 2C, comprising a matrix-array of diodes of square shape;

FIGS. 3A and 3B are partial and schematic cross-sectional views of an optoelectronic device according to two variants of the second embodiment;

FIGS. 4A to 4N illustrate, schematically and partially, via cross-sectional views, various steps of a process for fabricating an optoelectronic device according to the second embodiment and similar to that illustrated in FIG. 1B.

### DETAILED DISCLOSURE OF PARTICULAR EMBODIMENTS

In the figures and in the remainder of the description, the same references have been used to designate identical or similar elements. In addition, the various elements are not shown to scale for the sake of clarity of the figures. Moreover, the various embodiments and variants are not mutually exclusive and may be combined with one another. Unless indicated otherwise, the terms “substantially”, “about” and “of the order of” mean to within 10%. Moreover, the expression “comprising a” should be understood to mean “comprising at least one”, unless indicated otherwise.

The invention generally relates to an optoelectronic device comprising at least one diode, and preferably a matrix-array of diodes, each comprising a semiconductor portion encircled, in a main plane of the diode, by a peripheral piezoelectric portion. The semiconductor portion of the diode is intended to be strained as a result of a deformation of the peripheral piezoelectric portion in the main plane of the diode. The peripheral piezoelectric portion is deformed via an inverse piezoelectric effect. The tensile strain experienced by the semiconductor portion then result in a modification of the optical and/or electrical properties of the diode, such as, for example, a widening of the spectral range of absorption of light radiation in the case of a photodiode. The induced tensile strain may also be sufficient to make the band structure of the semiconductor compound substantially direct, in the case where the latter has an indirect band structure when it is in the relaxed state. The performance of the optoelectronic device may then be improved, notably in the case of a light-emitting diode.

By strained portion, what is meant is a portion made of a crystalline semiconductor compound that experiences a tensile or compressive mechanical stress so as to deform the unit cells of its crystal lattice. The portion is tensilely strained when it experiences a mechanical stress that tends to stretch the unit cells of the lattice in a plane. In the context of the invention, the semiconductor portion is intended to be tensilely strained in a main plane of the diode. This means that its lattice parameter, in the main plane, has a value, referred to as its effective value, higher than its natural value, i.e. its value when the semiconductor compound is relaxed (i.e. unstrained). In the rest of the description, unless otherwise indicated, the strain in question is oriented in the main plane of the photodiode.

The semiconductor compound, which thus experiences a tensile mechanical strain, therefore exhibits modified optical and/or electrical properties. In particular, its band gap, in particular that associated with the Γ valley (or direct valley) may be narrower. The band gap may be estimated depending on the tensile strain, as described in the case of a germanium layer in the publication by Guilloy et al. titled Germanium under high tensile stress: Nonlinear dependence of direct band gap vs strain, ACS Photonics 2016, 3, 1907-1911. Moreover, the tensile mechanical strain experienced by the semiconductor portion may be sufficient for the band structure to become direct.

By direct or substantially direct band structure, what is meant is that the minimum energy E_{BC,L} of the conduction band of the L valley (or indirect valley) is higher than or substantially equal to the minimum of energy E_{BC,Γ} of the conduction band of the Γ valley (or direct valley), or in other words: ΔE=E_{BC,L}−E_{BC,Γ}≤0. By substantially equal, what is meant here is that this energy difference is of the order of magnitude or less than kT, where k is Boltzmann's constant and T the temperature of the material. Preferably, the semiconductor portion is made based on germanium, the band structure of which is indirect in the relaxed state (in other words ΔE<0) and becomes direct when it experiences a sufficient tensile deformation.

As detailed below, the semiconductor portion is tensilely strained as a result of the deformation of the peripheral piezoelectric portion via an inverse piezoelectric effect, in the main plane of the diode. By inverse piezoelectric effect, what is meant is the physical phenomenon of (expansive or compressive) deformation of the crystal structure of the piezoelectric material in response to the application of an electric field through it. As known, the strain field T experienced by the piezoelectric material depends on the electric field E and on the piezoelectric coefficient e, and the strain tensor [T] is equal to −[e][E].

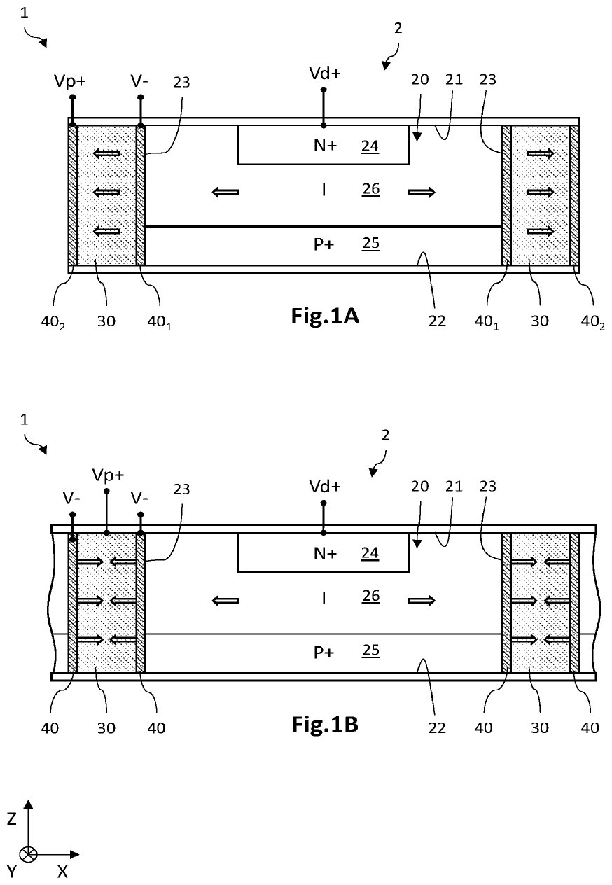

FIG. 1A is a partial and schematic cross-sectional view of an optoelectronic device 1 according to a first embodiment. In this example, the optoelectronic device 1 comprises at least one germanium photodiode 2 suitable for detecting light radiation in the near infrared corresponding to the spectral range extending from 0.8 μm to about 1.7 μm, or even to about 2.5 μm (SWIR, for Short Wavelength IR). As detailed below, the diode 2 is strained via an expansion of the peripheral piezoelectric portion 30, in the main plane of the diode, in a direction opposite to the semiconductor portion 20.

A three-dimensional direct coordinate system (X,Y,Z), in which the X- and Y-axes form a plane parallel to the main plane of the one or more diodes 2 of the optoelectronic device, and in which the Z-axis is oriented along the thickness of the semiconductor portion 20, is defined here and will be referred to in the rest of the description.

The optoelectronic device 1 comprises at least one diode 2 comprising a PN or PIN junction, the semiconductor portion 20 of the diode being encircled by a peripheral piezoelectric portion 30. It also comprises an electrical circuit for biasing the peripheral piezoelectric portion 30, this circuit being intended to generate, in the first embodiment, a deformation of the peripheral piezoelectric portion 30 in the main plane of the diode 2 and in a direction opposite to the semiconductor portion 20. Consequently, the latter experiences a tensile mechanical strain in the same main plane. The optoelectronic device also comprises an electrical circuit for biasing diode 2.

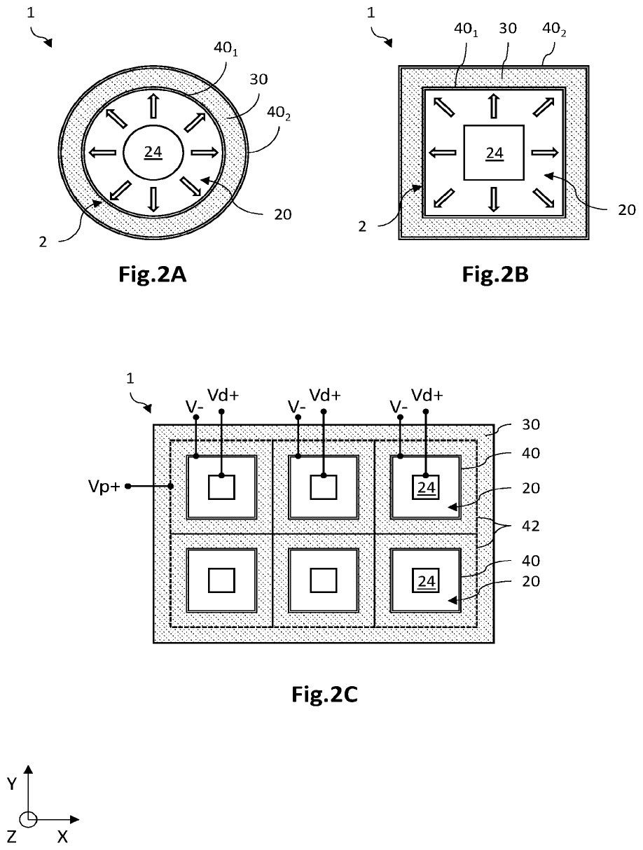

The semiconductor portion 20 extends about a main plane, here parallel to the XY-plane, and has a first face 21 and an opposite second face 22 that are substantially parallel to the XY-plane. These faces are connected to each other by a lateral border 23 which laterally bounds the semiconductor portion 20 in the XY-plane. In this example, the first and second faces 21, 22 are substantially planar, and hence the semiconductor portion 20 has a substantially uniform thickness. The lateral border 23 here advantageously lies parallel to the Z-axis, i.e. it is substantially orthogonal to the XY-plane. As illustrated in FIGS. 2A and 2B, the semiconductor portion 20 may have various shapes in the XY-plane, for example a circular shape (FIG. 2A) or a square shape (FIG. 2B). Other shapes are possible.

The semiconductor portion 20 is made based on a crystalline semiconductor compound of interest, which is preferably single-crystal. By “based on”, what is meant is that the material is an alloy formed from at least the same chemical elements as the semiconductor compound of interest. The semiconductor portion 20 may thus be a layer or a substrate made of the same semiconductor compound of interest and comprise regions of various conductivity types (homojunction) so as to form the PN or PIN junction. It may as a variant be a stack of sublayers of various semiconductor compounds (heterojunction) that are alloys of the semiconductor compound of interest.

Generally, the semiconductor compound of interest is advantageously chosen from materials based on germanium, such as germanium Ge, silicon-germanium SiGe, germanium-tin GeSn, and silicon-germanium-tin SiGeSn. Preferably, the semiconductor compound of interest has, in the absence of a tensile deformation of its crystal lattice, a first direct-bandgap value, and, when it experiences a tensile deformation, a second direct-bandgap value lower than the first value. In this example, the semiconductor portion 20 is obtained from a layer made of the same semiconductor compound, namely here of germanium.

The semiconductor portion 20 has a thickness along the Z-axis that may be comprised between a few hundred nanometers and a few microns, and for example comprised between about 1 m and 5 μm. In the case of a photodiode, the thickness is chosen so as to obtain good absorption in the wavelength range of the light radiation to be detected. It has a transverse dimension in the XY-plane that may be comprised between a few hundred nanometers and a few tens of microns, and for example between about 1 μm and 10 μm.

A PN or PIN junction is formed in the semiconductor portion 20. It is formed by two regions of the semiconductor portion 20 having different conductivity types. More precisely, it comprises a first region 24 doped according to a first conductivity type, n-type for example, and a second region 25 doped according to a second conductivity type opposite the first type, p-type for example.

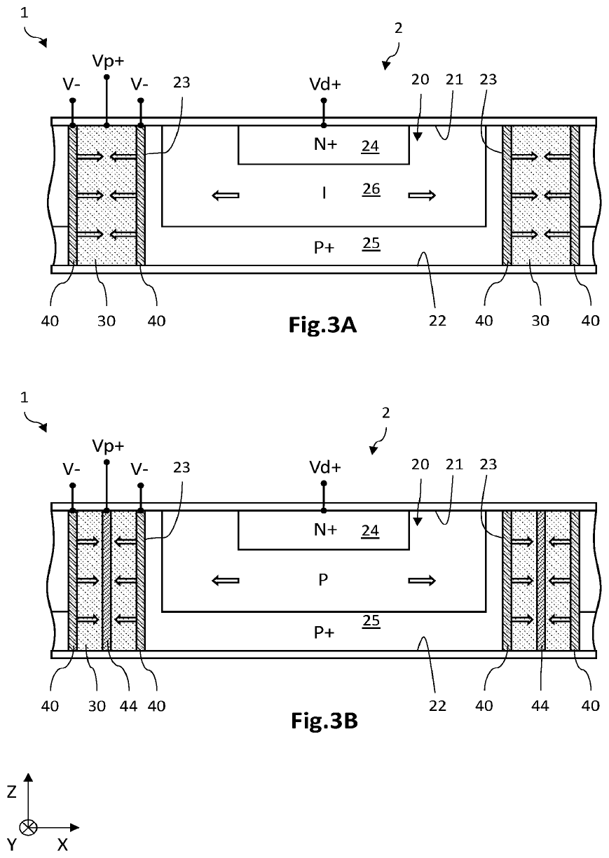

The junction may thus be a PN or PIN junction. In the examples of FIGS. 1A and 3A, the junction is a PIN junction, and hence the semiconductor portion 20 comprises an intrinsic, i.e. unintentionally doped, region 26 that extends between and makes contact with the n-doped first region 24 and the p-doped second region 25. In the example of FIG. 3B, the junction is a PN junction, and hence the n-doped first region 24 is encircled by and makes contact with the p-doped second region 25.

The n-doped first region 24 here extends along the Z-axis from the first face 21 and is away from the lateral border 23 in the XY-plane. It thus forms an n-doped well that is flush with the first face 21 and is spaced apart by a non-zero distance from the lateral edge 23 and the second face 22. By flush, what is meant is to “reach the level of”, or “extend from”. The doped first region 24 thus contributes to the definition of the first face 21. It is electrically isolated from the lateral border 23. The n-doped first region 24 may have a dopant density that may be comprised between about 1×10¹⁹ and 1×10²⁰ at/cm³.

The p-doped second region 25 extends from the lateral border 23, in the XY-plane, preferably continuously, i.e. it remains flush with the lateral border 23 preferably over the entire periphery of the semiconductor portion 20. It here extends along the Z-axis from the second face 22. It may, as illustrated in FIG. 1A, have a thickness that is substantially uniform along the Z-axis and thus be flush with a lower zone of the lateral border 23. As a variant, as illustrated in FIGS. 3A and 3B, the p-doped second region 25 may have a lateral zone that is flush with the entire surface of the lateral border 23, both along the Z-axis and around the entire periphery of the semiconductor portion 20. The p-doped second region 25 may have a dopant density that may be comprised between about 1×10¹⁹ and 1×10²⁰ at/cm³. The p-doped second region 25 is preferably overdoped so as to make a good ohmic contact with the peripheral conductive layer 40 mentioned below.

The optoelectronic device 1 according to the first embodiment comprises two concentric, peripheral conductive layers 40₁, 40₂. A first peripheral conductive layer 40₁ makes contact with the lateral border 23 of the semiconductor portion 20 and is suitable for participating in electrically biasing the diode 2 and in electrically biasing the peripheral piezoelectric portion 30. The second peripheral conductive layer 40₂ is arranged so that the peripheral piezoelectric portion 30 is interposed, in the XY-plane, between the two peripheral conductive layers 40₁, 40₂.

The first peripheral conductive layer 40₁ extends, in the main plane, in contact with the p-doped second region 25 so as to encircle the semiconductor portion 20. It therefore makes contact with the lateral border 23 of the semiconductor portion 20, and more precisely with the p-doped second region 25, which is flush with the lateral border 23, and therefore allows an electrical potential V− to be applied to the p-doped second region 25. It thus at least partially covers the lateral border 23, and preferably entirely covers it as illustrated in FIG. 1A. It at least partially encircles the semiconductor portion 20, and preferably entirely encircles the semiconductor portion 20 as illustrated in FIGS. 1B and 1C, so as to contribute to making, around the periphery of the semiconductor portion 20, the tensile mechanical strain experienced by the semiconductor portion 20 due to the deformation of the peripheral piezoelectric portion more uniform.

The first peripheral conductive layer 40₁ is formed from one or more conductive sublayers, and is made of at least one electrically conductive material, for example of TiN, Ti, NiCr, Al, Au, Pt, W, Ni, Cu, Mo etc. It has a thickness that is preferably substantially constant over its areal extent and that is, for example, comprised between about 10 nm and 100 nm. Preferably, it has a height along the Z-axis at least equal to the thickness of the semiconductor portion 20, and thus entirely covers the lateral border 23 along the Z-axis.

The optoelectronic device 1 comprises a peripheral piezoelectric portion 30, here designed to undergo a deformation in the main plane of the diode 2 in a direction opposite to the semiconductor portion 20, via an inverse piezoelectric effect, thus causing a tensile mechanical strain to form in the semiconductor portion 20 in the main plane of the diode, i.e. in the XY-plane.

The peripheral piezoelectric portion 30 extends, in the main plane, in contact with the first peripheral conductive layer 40₁ so as to encircle the semiconductor portion 20. There is therefore physical and electrical contact between the peripheral piezoelectric portion 30 and the first peripheral conductive layer 40₁, which is therefore suitable for applying an electric potential to the peripheral piezoelectric layer. It thus at least partially covers the first peripheral conductive layer 40₁ along the Z-axis, and preferably entirely is as illustrated in FIG. 1A. It at least partially encircles the semiconductor portion 20, and preferably entirely encircles the semiconductor portion 20, as illustrated in FIGS. 1B and 1C, so as to contribute to making, around the periphery of the semiconductor portion 20, the tensile mechanical strain experienced by the semiconductor portion 20 due to the deformation of the peripheral piezoelectric portion 30 more uniform. It thus extends around all or part of the periphery of the semiconductor portion 20. Thus, the first peripheral conductive layer 40₁ is interposed, in the XY-plane, between the semiconductor portion 20 and the peripheral piezoelectric portion 30.

The peripheral piezoelectric portion 30 is formed from at least one piezoelectric material and preferably from lead zirconate titanate PbZrTiO₃ (PZT), but other materials, such as BaTiO₃, AlN, ZnO, LiNbO₃, Pb (NbO₃)₂, PbTiO₃, Pb(Mg_{0.33}Nb_{0.66})O₃, Pb(Sc_{0.5}Ta_{0.5})O₃ or any other suitable piezoelectric material may be used. The peripheral piezoelectric portion 30 preferably extends continuously around the semiconductor portion 20, so as to participate in making substantially uniform, around the periphery of the semiconductor portion 20, the tensile mechanical strain experienced by the latter. Preferably, it has a thickness along the Z-axis larger than or equal to that of the semiconductor portion 20, so as to participate in making substantially uniform, along the Z-axis, the tensile mechanical strain experienced by the semiconductor portion 20.

The optoelectronic device 1 here comprises a second peripheral conductive layer 40₂, which is preferably made of the same material or materials as the first peripheral conductive layer 40. It extends in contact with an external lateral flank of the peripheral piezoelectric portion 30 so as to encircle the latter in the XY-plane. Thus, the peripheral piezoelectric portion 30 comprises an internal lateral flank oriented toward the semiconductor portion 20 and making contact with the first peripheral conductive layer 40₁, and an external lateral flank, opposite the internal flank, making contact with the second peripheral conductive layer 40₂.

The optoelectronic device 1 comprises a first electrical circuit for biasing the peripheral piezoelectric portion 30, the electrical bias thus applied allowing the peripheral piezoelectric portion 30 to be deformed in the main plane and in a direction opposite to the semiconductor portion 20. To do this, the electrical circuit comprises metallizations (not shown) that make contact with the two peripheral conductive layers 40₁, 40₂, allowing a potential difference to be applied to the peripheral piezoelectric portion 30. The metallizations preferably rest on the first face 21, and make electrical contact with one end of the peripheral conductive layers 40₁, 40₂. They may be pads the dimensions of which in the XY-plane may be of the same order as their thickness, or be strips which extend longitudinally in contact with the peripheral conductive layers 40₁, 40₂, preferably over the entire length thereof. Thus, a negative electric potential V− may be applied to the first peripheral conductive layer 40₁, and a positive electric potential Vp+ may be applied to the second peripheral conductive layer 40₂.

Thus, in operation, a voltage for biasing the peripheral piezoelectric portion 30 is applied via the two peripheral conductive layers 40₁, 40₂, by bringing the first to the electric potential V− and the second to the electric potential Vp+. An electric field is then generated within the peripheral piezoelectric portion 30, the field lines of which extend substantially parallel to the XY-plane. Due to the orientation of the peripheral conductive layers 40₁, 40₂ along the Z-axis beside the peripheral piezoelectric portion 30, the generated electric field has a non-zero component in the XY-plane, and thus induces a deformation in the XY-plane of the peripheral piezoelectric portion 30 via an inverse piezoelectric effect, in a direction opposite to the semiconductor portion 20 (shown by the arrows). Insofar as, on the one hand, the peripheral piezoelectric portion 30 encircles the semiconductor portion 20, and, on the other hand, there is a continuity of material between the peripheral piezoelectric portion 30 and the semiconductor portion 20 in the XY-plane, the mechanical stresses experienced by the peripheral piezoelectric portion 30 are transmitted to the semiconductor portion 20, so that the semiconductor portion 20 then experiences a tensile mechanical strain in the XY-plane, i.e. in the main plane.

FIG. 1B is a partial and schematic cross-sectional view of an optoelectronic device 1 according to a second embodiment. In this example, the optoelectronic device 1 comprises a matrix-array of diodes 2 that are adjacent in the XY-plane and substantially coplanar. The diodes 2 are here germanium photodiodes 2 suitable for detecting light radiation in the near infrared. As detailed below, the diodes 2 are strained via a compression of the peripheral piezoelectric portion 30, in the main plane of the diode.

The optoelectronic device 1 according to this embodiment differs from that illustrated in FIG. 1A essentially in that a peripheral conductive layer 40 that is interposed between the semiconductor portion 20 and the peripheral piezoelectric portion 30 is associated with each diode 2. The other peripheral conductive layer 40 illustrated in FIG. 1B is that associated with the adjacent diodes 2. Furthermore, the adjacent conductive layers are preferably brought to the same negative electric potential V−. Moreover, the piezoelectric material is chosen from electrically insulating materials, so as to electrically isolate the diodes 2.

It thus comprises a first metallization (not shown) for biasing the peripheral conductive layer 40, this metallization preferably resting on the first face 21 of the optoelectronic device 1 and making electrical contact with one end of said peripheral conductive layer 40.

It also comprises, in this example, a second metallization 42 (illustrated by dashed lines in FIG. 2C) for biasing the peripheral piezoelectric portion 30, this metallization preferably resting on the first face 21 and making contact with the piezoelectric material. The second metallization 42 may be a plurality of pads arranged so as to encircle the semiconductor portion 20, or may be a strip that extends so as to continuously encircle the semiconductor portion 20. It is preferably located between each adjacent peripheral conductive layer 40, in the XY-plane. A positive electric potential Vp+ may thus be applied to the peripheral piezoelectric portion 30 by way of this metallization.

Thus, in operation, a biasing voltage is applied to the peripheral piezoelectric portion 30, thus generating an electric field in the peripheral piezoelectric portion 30, the field lines of which extend between the peripheral conductive layer 40 and the second metallization 42. Due to the orientation of the peripheral conductive layer 40 along the Z-axis beside the peripheral piezoelectric portion 30, the generated electric field has a non-zero component in the XY-plane, and thus induces a compressive deformation in the XY-plane of the peripheral piezoelectric portion 30 via an inverse piezoelectric effect. Insofar as, on the one hand, the peripheral piezoelectric portion 30 encircles the semiconductor portion 20, and, on the other hand, there is a continuity of material between the peripheral piezoelectric portion 30 and the semiconductor portion 20 in the XY-plane, the mechanical stresses experienced by the peripheral piezoelectric portion 30 are transmitted to the semiconductor portion 20, so that the semiconductor portion 20 then experiences a tensile mechanical strain in the XY-plane.

The optoelectronic device 1 according to the first and second embodiments comprises a second electrical circuit for biasing the one or more diodes 2, so as to allow light radiation to be emitted or detected.

To do this, the electrical circuit comprises metallizations (not shown) allowing the one or more diodes 2 to be forward or reverse biased, depending on whether the diode is employed to emit or detect. Thus, in the case of a photodiode, a first metallization is located on and in contact with the n-doped first region 24, and is suitable for applying a positive electric potential Vd+ to the latter. A negative potential V− is applied to the p-doped second region 25 by way of the peripheral conductive layer 40 with which it makes contact. Thus, the electric potential applied to the peripheral conductive layer 40 not only allows the peripheral piezoelectric portion 30 to be biased in order to induce a compressive deformation thereof, but also allows the diode 2 to be biased (here reverse biased).

FIG. 2C is a schematic and partial view from above of an optoelectronic device 1 that is identical to that illustrated in FIG. 1B, the diodes 2 of which have a square shape. The diodes 2 are electrically isolated from each other by the peripheral piezoelectric portion 30, which here extends continuously in the XY-plane. Each diode 2 comprises a peripheral conductive layer 40 interposed in the XY-plane between the semiconductor portion 20 and the peripheral piezoelectric portion 30. The first electrical circuits comprise a metallization 42 (dashed lines) for biasing the peripheral piezoelectric portion 30, which metallization extends longitudinally on the first face 21 around each diode 2. The metallization 42 is brought to a positive electric potential Vp+ and each peripheral conductive layer 40 is brought to a negative electric potential V−, thus making it possible to generate, in the peripheral piezoelectric portion 30, an electric field capable of causing the compressive deformation of the latter. Moreover, each n-doped first region 24 is brought to a positive electric potential Vd+. Thus, each diode 2 is here reverse biased, thus allowing photodetection of the infrared light radiation. Each peripheral conductive layer participates in biasing, at the same time, the peripheral piezoelectric portion 30 and the corresponding semiconductor portion 20.

FIG. 3A is a partial and schematic cross-sectional view of a variant of the optoelectronic device 1 according to the second embodiment illustrated in FIG. 1A. The optoelectronic device 1 essentially differs therefrom in that the p-doped second region 25 comprises a lateral zone, which is preferably also overdoped, and which is flush with the lateral border 23 over the entire height of the latter along the Z-axis, and around the entire periphery of the semiconductor portion 20 in the XY-plane. Thus, the bias of the p-doped second region 25 is improved insofar as the area of the ohmic contact with the peripheral conductive layer 40 is increased. In addition, such a configuration of the PIN junction makes it possible to prevent the space charge region between the n- and p-doped regions from extending up to the lateral border 23. The contribution of this region (which is potentially not free from defects related to the production of the trenches) to the dark current is thus limited. This variant also applies to the optoelectronic device 1 according to the first embodiment.

FIG. 3B is a partial and schematic cross-sectional view of a variant of the optoelectronic device 1 according to the second embodiment illustrated in FIG. 3A. The optoelectronic device 1 notably differs therefrom in that the diode 2 comprises a PN junction and not a PIN junction, as could also be the case in the first embodiment of FIG. 1A. Moreover, the p-doped second region 25 may comprise an overdoped zone that is flush with the lateral border 23 and here with the second face 22, and a zone of lower p-dopant level, which encircles the n-doped well. It also differs therefrom in that there is a conductive layer 44 interposed between the peripheral conductive layer 40 that makes contact with the semiconductor portion 20 in question and the peripheral conductive layer that makes contact with the semiconductor portion 20 of a neighboring diode 2. This interposed conductive layer 44 here extends substantially parallel to the peripheral conductive layer 40 along the Z-axis, and encircles the semiconductor portion 20 in the XY-plane. It is brought to the positive electric potential Vp+. Thus, the electric field generated between the intermediate conductive layer 44 and the peripheral conductive layer 40 essentially comprises a component parallel to the XY-plane, this thus improving the magnitude of the compressive deformation of the piezoelectric material, and the deformation uniformity along the Z-axis. The semiconductor portion 20 then experiences a tensile strain the uniformity of which along the Z-axis is also improved.

The optoelectronic device 1 then has the advantage of allowing the semiconductor portion 20 of the one or more diodes 2 to be strained in an active manner, i.e. by using a voltage to bias the piezoelectric material. As detailed above, biasing the piezoelectric material may induce a deformation of the peripheral piezoelectric portion 30 in the XY-plane in a direction opposite to the semiconductor portion 20 (first embodiment illustrated in FIG. 1A), or a compressive deformation in the XY-plane (second embodiment illustrated in FIG. 1B). The value of the tensile strain may be controlled in a precise and simplified manner, insofar as it mainly depends on the magnitude of the voltage biasing the piezoelectric material, and not on a strain-generating technology based on deposition of a stack of thin layers or structuring of the semiconductor portion 20 followed by release thereof. Thus, an optoelectronic device 1 is obtained the optical and/or electrical properties of which may be controllably modified, i.e. here actively, during the operation of the optoelectronic device 1, by modulating the voltage biasing the piezoelectric material. It is thus possible to widen the spectral range of absorption of the optoelectronic device 1, for example so as to obtain a cut-off wavelength longer than 1550 nm in the case of a germanium photodiode 2. It is also possible, notably in the context of a telecom application, to modulate the signal-to-noise ratio associated with the photodiode, by varying the voltage biasing the piezoelectric material.

In addition, the optoelectronic device 1 has a small bulk, insofar as the peripheral piezoelectric portion 30 is substantially coplanar with the semiconductor portion 20 of the one or more diodes 2. The piezoelectric material mainly covers the lateral border 23 of the semiconductor portion 20 and preferably does not cover the first face 21 and/or the second face 22 of the diode. Such an arrangement of the peripheral piezoelectric portion with respect to the diodes 2 also permits a high spatial density of diodes 2 to be achieved, and therefore an optoelectronic device 1 of high spatial resolution to be obtained in the case where the latter comprises a matrix-array of diodes 2.

By way of example, the optoelectronic device 1 may comprise a photodiode 2 the semiconductor portion 20 of which is circular and made of germanium. The n-doped first region 24 may have a diameter of about 3 μm and the semiconductor portion 20 may have a diameter of about 8 m. It is bordered by a peripheral piezoelectric portion 30 made of PZT with a transverse dimension of about 1 μm. A peripheral conductive layer 40 made of TiN is interposed between the peripheral piezoelectric portion 30 and the peripheral conductive layer 40. A study by numerical simulation has allowed it to be demonstrated that using a voltage of about +5 V to bias the peripheral piezoelectric portion 30 allows the semiconductor portion 20 to be deformed by 0.5 nm in the XY-plane. Such a strain then allows the cut-off wavelength of germanium to be increased tensilely to a value longer than 1550 nm.

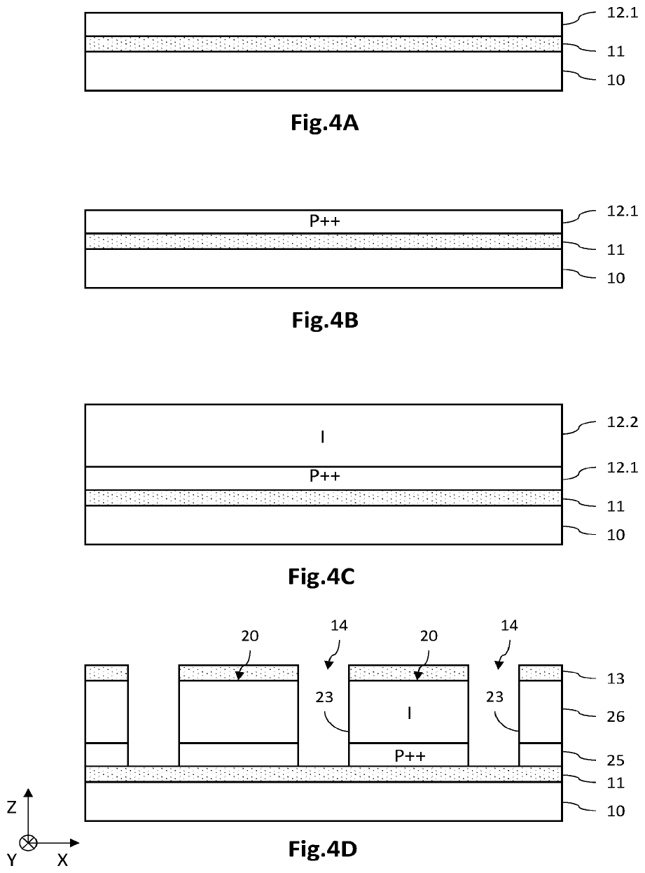

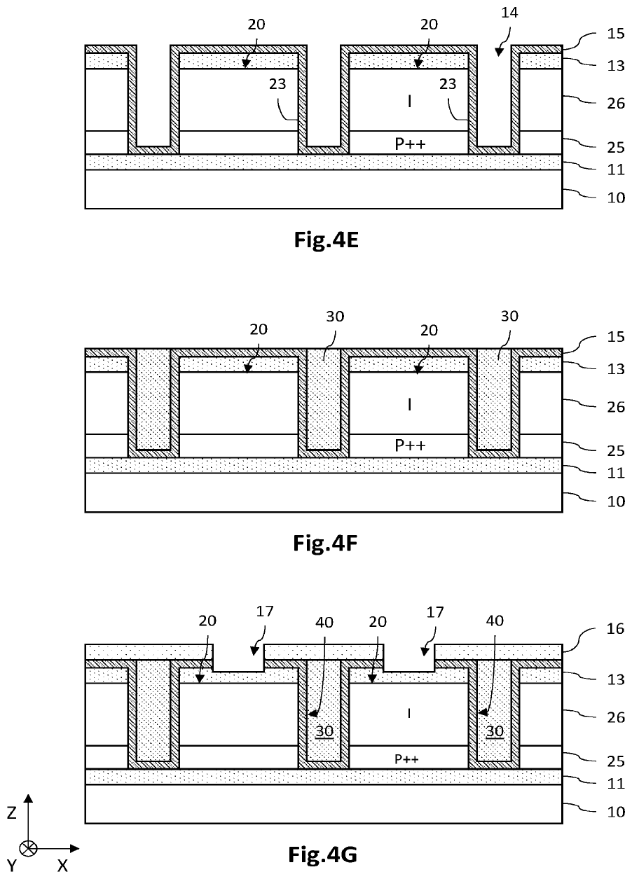

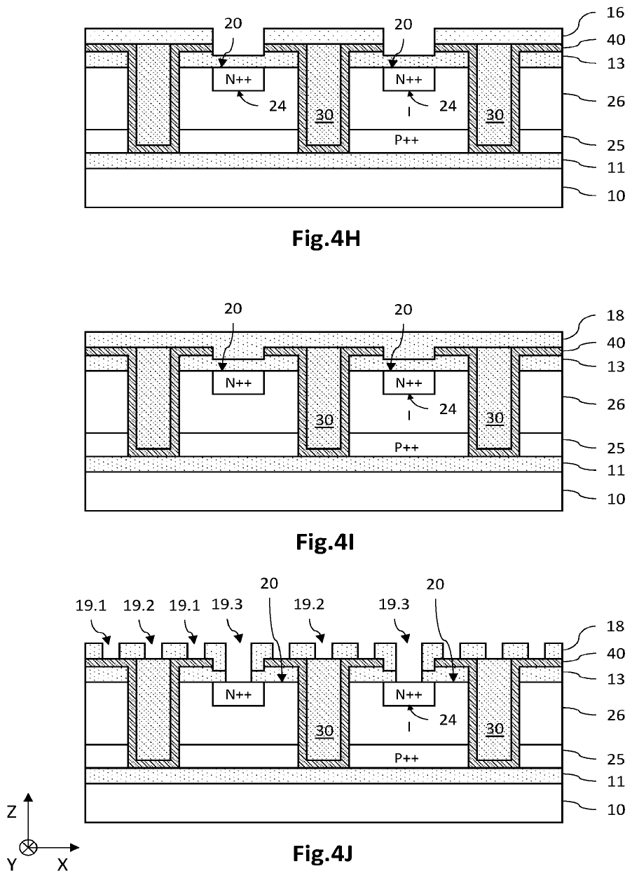

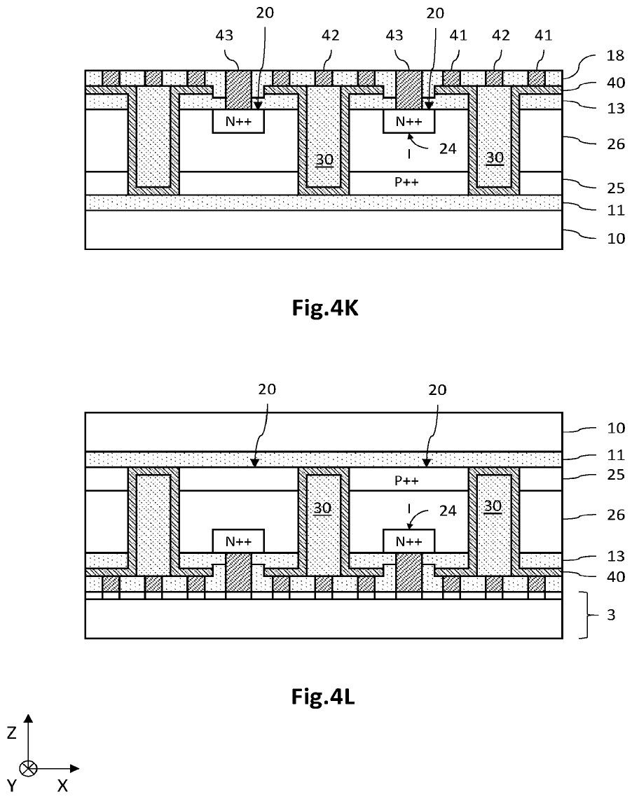

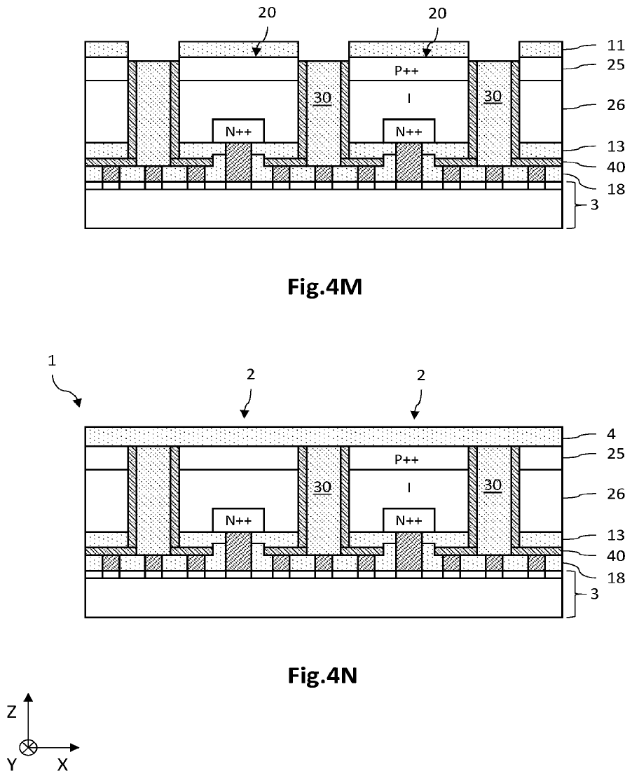

An example of a process for fabricating an optoelectronic device 1 according to the second embodiment and identical or similar to that illustrated in FIG. 1B will now be described with reference to FIGS. 4A to 4N. In this example, the diodes 2 are photodiodes with PIN junctions made from germanium and are suitable for detecting infrared radiation in the SWIR range.

In a first step (FIG. 2A), a first semiconductor sublayer 12.1 of single-crystal germanium is produced. The first semiconductor sublayer 12.1 is attached to a carrier layer 10, here made from silicon, by way of a lower dielectric layer 11, here made of a silicon oxide. This stack takes the form of a GeOI substrate (GeOI standing for germanium-on-insulator). This stack is preferably produced by means of the process described in the publication by Reboud et al. entitled Structural and optical properties of 200 mm germanium-on-insulator (GeOI) substrates for silicon photonics applications, Proc. SPIE 9367, Silicon Photonics X, 936714 (Feb. 27, 2015). Such a process has the advantage of producing a germanium semiconductor sublayer 12.1 containing a low level of structural defects such as dislocations. The germanium may be unintentionally doped or doped, p-type for example. The semiconductor sublayer 12.1 may have a thickness comprised between about 100 nm and 500 nm, and for example equal to about 300 nm, and may be covered with a protective layer (not shown) made of a silicon oxide.

In a following step (FIG. 4B), the first germanium sublayer 12.1 is doped according to the second conductivity type, here p-type, by ion implantation of a dopant such as boron. The protective layer, where appropriate, will have been removed beforehand by surface cleaning, and the first germanium sublayer 12.1 may be coated with a pre-implantation oxide layer of a thickness of a few tens of nanometers, and for example equal to 20 nm. The germanium sublayer 12.1 then has a dopant density comprised between about 1×10¹⁹ and 1×10²⁰ at/cm³. A anneal may then be carried out under nitrogen, for a few minutes to a few hours, for 1 hour for example, at a temperature which may be comprised between 600° C. and 8000° C., and that is for example equal to 800° C., in order to diffuse the dopant. This step allows the germanium sublayer 12.1 to be overdoped, improving the ohmic contact between the p-doped second region 25 and the peripheral conductive layer 40.

In a following step (FIG. 4C), a second germanium semiconductor sublayer 12.2 is produced epitaxially from the first sublayer 12.1. The two sublayers are intended to form the germanium semiconductor portions 20 of the matrix-array of diodes 2. The second sublayer 12.2 is formed epitaxially, for example by chemical vapor deposition (CVD) or by any other epitaxial growth technique. The pre-implementation oxide layer, where appropriate, will have been removed beforehand by surface cleaning. The second germanium sublayer 12.2 is intrinsic here, that is to say unintentionally doped. It is intended to form the light absorption zone of the diodes 2. Its thickness depends on the wavelength range of the light radiation to be detected in the case of a photodiode 1. In the context of SWIR photodiodes 2, the intrinsic germanium sublayer 12.2 has a thickness for example comprised between 0.5 μm and 3 μm, and preferably equal to 1.5 μm.

In a following step (FIG. 4D), the germanium semiconductor layer formed from the two sublayers is etched locally with the aim of forming a continuous trench 14 in the XY-plane so as to pixelate the diodes 2. To do this, an upper dielectric layer 13 is preferably deposited beforehand on the exposed face of the semiconductor layer. The upper dielectric layer 13 may have a thickness of a few tens to a few hundred nanometers, and for example comprised between about 20 nm and 300 nm, and for example equal to about 100 nm. The trench 14 is produced using conventional photolithography and etching techniques. A localized zone of the upper dielectric layer 13, of the second sublayer 12.2 of intrinsic germanium and of at least some of the thickness of the first sublayer 12.1 of overdoped germanium is thus etched. A plurality of germanium semiconductor portions that are separated from one another by the continuous trench 14 are thus obtained. The trench 14 is preferably obtained by an anisotropic etching technique, so as to obtain a lateral border 23 of the semiconductor portions 20 that is substantially planar along the Z-axis, and preferably substantially orthogonal to the XY-plane. The continuous trench 14 has a transverse dimension (width) in the XY-plane that may be comprised between 300 nm and 30 μm, and that is for example comprised between about 1 μm and 2 μm. It extends longitudinally in the XY-plane so as to bound the semiconductor portions 20. The latter may thus have, in the XY-plane, a shape that is, for example, circular, oval or polygonal, square for example, or any other shape.

In this example, the first sublayer 12.1 is etched locally right through its thickness, so as to uncover the lower dielectric layer 11. As a variant (not shown), the first sublayer 12.1 may be partially etched locally, so as to leave behind a continuous lower portion of overdoped germanium, with the aim of increasing the area of ohmic contact between the p-doped second region 25 and the peripheral conductive layer 40.

To obtain a p-doped second region 25 that comprises a lateral zone that extends along the lateral border 23 and the Z-axis, and around the circumference of the semiconductor portion 20 in the XY-plane (as illustrated in FIGS. 3A and 3B), an additional ion implantation, for example of boron, may be carried out with a non-zero angle of inclination, so as to dope the side wall of the semiconductor portions 20.

In a following step (FIG. 4E), a continuous conductive layer 15 is deposited conformally on the exposed surface of the structure obtained beforehand. The conductive layer is made of at least one electrically conductive material, and here of TiN. It may be deposited by chemical vapor deposition (CVD) and continuously covers the lateral border 23 of the semiconductor portions 20, the upper dielectric layer 13 and here the exposed surface of the lower dielectric layer 11. This continuous conductive layer 15 is intended to form the peripheral conductive layers that make contact with the lateral border 23, with a view to joint biasing the p-doped second region 25 and the peripheral piezoelectric portion 30. The continuous conductive layer 15 may have a thickness comprised between about 10 nm and 100 nm.

Ina following step (FIG. 4F), the peripheral piezoelectric portion 30 is produced. To do this, a piezoelectric material, here for example PZT, is deposited so as to continuously cover the structure obtained beforehand and therefore to fill the trench 14. The piezoelectric material thus makes contact with the continuous conductive layer. It may be deposited by physical vapor deposition (PVD) or by any other suitable technique. The peripheral conductive layer 40, notably when it is made of TiN, ensures the piezoelectric material bonds well, in particular when it is PZT. The piezoelectric material is preferably dielectric, so as thus to electrically isolate the photodiodes 2. An annealing step may be carried out, for example at between 300° C. and 700° C., to optimize the piezoelectric properties of the material. A planarizing step, for example a step of chemical-mechanical polishing (CMP), is then carried out, this step being stopped on the top part of the continuous conductive layer.

In a following step (FIG. 4G), zones in which dopants are to be implanted ionically, with a view to forming the n-doped first regions 24, are defined. To do this, a photoresist 16 is deposited, apertures 17 of which are located opposite the semiconductor portion 20. Localized etching is then carried out on an upper zone of the continuous conductive layer 15 and preferably on some of the upper dielectric layer 13. The transverse dimensions, in the XY-plane, of the localized etch substantially correspond to those of the n-doped first regions 24 that it is desired to obtain. These transverse dimensions thus depend on those of the semiconductor portion 20, and may be comprised, for example, between 300 nm and 10 μm.

In a following step (FIG. 4H), the n-doped first portions are produced by ion implantation of a dopant such as phosphorus, through the apertures 17. The first regions 24 are preferably overdoped, and may thus have a dopant density comprised between about 1×10¹⁹ and 1×10²⁰ at/cm 3. The n-doped first regions 24 thus form n-doped wells bounded in the XY-plane and in the −Z-direction by the second sublayer 12.2 of intrinsic germanium. A resistive contact is thus formed at the interface between the peripheral conductive layer 40 and the intrinsic germanium of the second sublayer 12.2. An anneal may be carried out, for example at a temperature comprised between 400° C. and 700° C. for a time between a few seconds and a few tens of minutes, and for example at 6000° C. for 30 s, to diffuse the dopants.

In the following steps (FIGS. 4I and 4J), an additional dielectric layer 18 is deposited with the aim of then producing the biasing metallizations. To do this, the photoresist 16 is removed and then the dielectric layer (FIG. 4I), which is for example made of a silicon oxide or of a tetraethyl orthosilicate (TEOS), is deposited so as to completely cover the structure obtained beforehand. The dielectric layer 18 may have a thickness comprised between 50 nm and 200 nm, for example. Next, first through-apertures 19.1 are produced in the dielectric layer (FIG. 4J) by photolithography and etching, with the etching stopped on the peripheral conductive layer 40, with a view to forming the metallizations 41 for biasing the peripheral conductive layer. The apertures thus open onto an upper zone of the peripheral conductive layer 40 that extends over the upper dielectric layer 13. Furthermore, second through-apertures 19.2 are produced with a view to forming metallizations 42 for biasing the peripheral piezoelectric portion 30, and third apertures 19.3 are produced with a view to forming metallizations 43 for biasing the n-doped first regions 24. The second apertures 19.2 may extend longitudinally so as to encircle each diode 2 in the XY-plane. In other words, each diode 2 is encircled by a given second aperture 19.2 that may extend longitudinally in a continuous or even discontinuous manner. The apertures 19.1, 19.2, 19.3 may have transverse dimensions in the XY-plane comprised between a few hundred nanometers and a few microns, depending on the dimensions of the diodes 2 and on the width of the peripheral piezoelectric portion 30.

In a following step (FIG. 4K), the metallizations 41, 42, 43 are produced through the through-apertures 19.1, 19.2, 19.3. The metallizations 41, 42, 43 are made of at least one metal, and may be formed from a barrier layer, for example of TiN deposited by CVD, followed by a copper layer. A planarizing step, for example a step of CMP, is then carried out, this step being stopped on the protective upper layer of protective oxide.

In a following step (FIG. 4L) the structure thus obtained is then assembled mechanically and electrically with a control chip 3, this also being referred to as hybridization. The hybridization may be achieved by direct copper/copper and/or oxide/oxide bonding, or by any other hybridization technique.

In a following step (FIG. 4M) the silicon carrier layer 10 is advantageously removed, for example by grinding and/or by wet etching or dry (RIE, ICP, etc.) plasma etching, with the etching stopped on the lower dielectric layer 11. It is also possible to carry out the localized etching of the lower dielectric layer 11 and continuous conductive layer, so as to uncover a face of the peripheral piezoelectric portion 30. Thus, the lower dielectric layer 11 ensures the passivation of the semiconductor portion 20.

In a following step (FIG. 4N), the remaining lower dielectric layer 11 may be removed, so as to also uncover the second face 22 of the semiconductor portion 20, and an at least partially transparent dielectric layer 4 then deposited. This layer 4 protects the diodes 2, passivates the second face 22 of the semiconductor portions 20, and may also perform an antireflection optical function when its thickness is a multiple of λ/4n, where λ is a wavelength of the light radiation to be detected and n is the refractive index of the material of the antireflection layer. Such a layer 4 may be made of an oxide or nitride of silicon, SiO₂, SiN or Si₃N₄ for example, or of aluminum, AlN or Al₂O₃ for example. Its thickness may for example be comprised between about 20 nm and 200 nm.

Thus, this fabricating process allows an optoelectronic device 1 comprising a matrix-array of diodes 2 the semiconductor portions 20 of which may be actively strained, i.e. strained by applying a potential difference to the peripheral piezoelectric portion 30 encircling each diode so as to deform it, to be obtained. Moreover, the optoelectronic device 1 may have a high spatial resolution, and a low bulk, insofar as the peripheral piezoelectric portion 30 is coplanar with the diodes 2. In addition, the peripheral piezoelectric portion 30 defines, with the diodes 2, a substantially planar optoelectronic structure, bounded along the Z-axis by two substantially planar faces, this contributing to decrease the bulk of the optoelectronic device 1. Moreover, the diodes 2 have good optical and/or electronic properties, notably insofar as potential structural defects such as dislocations remain mainly confined to the p-doped second region 25 and not to the intrinsic region 26.

Moreover, it is advantageous for the first regions 24 to be n-doped and for the second regions 25 to be p-doped in terms of the length of the diffusion anneal. Specifically, the boron used for the p-doping diffuses more slowly than the phosphorus used for the n-doping. Thus, the anneal carried out to diffuse the phosphorus, which requires a short length of time, is carried out after the anneal carried out to diffuse the boron, which for its part requires a longer length of time.

Particular embodiments have just been described. Various modifications and variants will be apparent to a person skilled in the art.

1. An optoelectronic device, comprising:
at least one diode, comprising a semiconductor portion having:
a first face and an opposite second face that are substantially parallel to a main plane and that are connected to each other by a lateral border, and
a PN or PIN junction formed by:
a first region that is doped according to a first conductivity type, and
a second region that is doped according to a second conductivity type opposite the first type and that extends from the lateral border;
a peripheral conductive layer that is made of at least one electrically conductive material and that extends, in the main plane, in contact with the second doped region so as to encircle the semiconductor portion;
a peripheral piezoelectric portion that is made of at least one piezoelectric material and that extends, in the main plane, in contact with the peripheral conductive layer so as to encircle the semiconductor portion; and
a first electrical circuit for biasing the peripheral piezoelectric portion, said circuit being configured to generate an electric field in the peripheral piezoelectric portion by applying an electrical potential at least to the peripheral conductive layer, so as to induce a deformation of the peripheral piezoelectric portion that is oriented in the main plane, thus causing the semiconductor portion to be tensilely strained in the main plane.

2. The optoelectronic device as claimed in claim 1, wherein the peripheral conductive layer and the peripheral piezoelectric portion encircle the semiconductor portion continuously.

3. The optoelectronic device as claimed in claim 1, wherein the peripheral conductive layer entirely covers the lateral border of the semiconductor portion along an axis orthogonal to the main plane, and the peripheral piezoelectric portion entirely covers the peripheral conductive layer along said orthogonal axis.

4. The optoelectronic device as claimed in claim 1, wherein the lateral border extends substantially orthogonally to the main plane.

5. The optoelectronic device as claimed in claim 1, wherein the peripheral piezoelectric portion has a thickness at least equal to that of the semiconductor portion.

6. The optoelectronic device as claimed in claim 1, comprising a second electrical circuit for biasing the diode, said circuit being configured to apply said electrical potential to the second doped region by way of the peripheral conductive layer and a different electrical potential to the first doped region.

7. The optoelectronic device as claimed in claim 1, wherein the first doped portion extends from the first face and is away from the lateral border.

8. The optoelectronic device as claimed in claim 1, wherein the diode comprises:
a PIN junction, the first doped region being encircled in the main plane and making contact with an unintentionally doped region, or
a PN junction, the first doped region being encircled in the main plane and making contact with the second doped region.

9. The optoelectronic device as claimed in claim 1, wherein the semiconductor portion is made based on germanium.

10. The optoelectronic device as claimed in claim 1, wherein the peripheral piezoelectric portion is made of PZT.

11. The optoelectronic device as claimed in claim 1, wherein the peripheral piezoelectric portion is, in the main plane, substantially coplanar with the diode.

12. The optoelectronic device as claimed in claim 1, comprising a matrix-array of coplanar diodes the semiconductor portions of which are electrically isolated from each other by a peripheral piezoelectric portion that, in the main plane, extends continuously.

13. The optoelectronic device as claimed in claim 12, comprising a metallization encircling each semiconductor portion and resting on an end of the peripheral piezoelectric portion that emerges onto the first face or the second face, the first circuit being configured to apply an electrical potential difference between the metallization and the peripheral conductive layer of each diode, so as to cause a compressive deformation of the peripheral piezoelectric portion in the main plane.

14. The optoelectronic device as claimed in claim 1, comprising a second peripheral conductive layer that is arranged so that the peripheral piezoelectric portion is interposed, in the main plane, between the second peripheral conductive layer and said peripheral conductive layer that makes contact with the semiconductor portion, the first circuit being configured to apply an electrical potential difference between said peripheral conductive layers, so as to cause a deformation of the peripheral piezoelectric portion in the main plane in a direction opposite to the semiconductor portion.

15. A process for fabricating an optoelectronic device as claimed in claim 1, comprising at least the following steps:
producing at least the semiconductor portion;
conformally depositing the peripheral conductive layer on and in contact with the lateral border of the semiconductor portion; and
forming the peripheral piezoelectric portion by depositing a piezoelectric material on and in contact with a face of the peripheral conductive layer that is opposite to the lateral border.
